(19) United States
(12) Patent Application Publication
(10) Pub. No.: US 2024/0105582 A1
(43) Pub. Date: Mar. 28, 2024

(54) LOW TEMPERATURE CAPACITIVELY COUPLED DEVICE FOR LOW NOISE CIRCUITS

(71) Applicant: Intel Corporation, Santa Clara, CA (US)

(72) Inventors: Abhishek Anil Sharma, Portland, OR (US); Tahir Ghani, Portland, OR (US); Anand Murthy, Portland, OR (US); Wilfred Gomes, Portland, OR (US); Sagar Suthram, Portland, OR (US); Pushkar Ranade, San Jose, CA (US)

(73) Assignee: Intel Corporation, Santa Clara, CA (US)

(21) Appl. No.: 17/955,262

(22) Filed: Sep. 28, 2022

(51) Int. Cl. H01L 23/522; H01L 23/473; H01L 23/50

(52) U.S. Cl. CPC H01L 23/5222; H01L 23/473; H01L 23/50

(57) ABSTRACT

An integrated circuit die includes a first conductive structure for an input of a capacitively coupled device, a second conductive structure aligned with the first conductive structure for a signal to be capacitively coupled to the input of the capacitively coupled device, a first insulator material disposed between the first conductive structure and the second conductive structure, wherein the first insulator material comprises high gain insulator material, and a cooling structure operable to remove heat from the capacitively coupled device to achieve an operating temperature at or below 0° C. Other embodiments are disclosed and claimed.

### BACKGROUND

Capacitive coupling generally refers to a transfer of energy in an electrical circuit by means of displacement current between nodes of the circuit, induced by an electric field. Capacitive coupling is often unintended, such as the capacitance between two wires that are close to each other. One signal may capacitively couple with another signal and cause unwanted noise. There is an ongoing need for improved computational devices to enable ever increasing demand for modeling complex systems, providing reduced computation times, and other considerations. In some contexts, scaling features of integrated circuits has been a driving force for such improvements. Other advancements have been made in materials, device structure, circuit layout, and so on. In particular, there is an ongoing desire to improve signal line structures that are included in or otherwise support operation of integrated circuits. It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a block diagram of an example integrated circuit (IC) die that includes one or more capacitively coupled devices (CCDs);

FIG. 2 illustrates a block diagram side view of an example of another IC die that includes one or more CCDs;

FIG. 3 illustrates a block diagram side view of an example of another IC die that includes one or more CCDs;

FIG. 4 illustrates a block diagram of an example of a system;

FIG. 5 illustrates a cross sectional side view of an example CCD;

FIG. 6 illustrates a cross sectional side view of an example of another IC die that includes one or more CCDs;

FIG. 7 illustrates a cross-sectional view of a low-temperature IC system with low temperature CCDs, using die- and package-level active cooling;

FIG. 8 illustrates a view of an example two-phase immersion cooling system for low-temperature operation of an IC die;

FIGS. 9A to 9B illustrates various processes or methods for forming low temperature CCDs on an IC die;

FIG. 10 illustrates a diagram of an example data server machine employing an IC die with low temperature CCDs; and

FIG. 11 is a block diagram of an example computing device, all in accordance with at least some implementations of the present disclosure.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve signaling in an integrated circuit (IC) at low temperature using capacitively coupled devices (CCDs). At room temperature, one problem is circuits experience thermal noise. Various conventional techniques may be utilized to reduce, inhibit, or otherwise deal with high noise at room temperature, but such techniques may involve significant energy dissipation. Some embodiments may overcome one or more of the foregoing problems. Some embodiments may provide technology for low temperature CCDs. Some embodiments may be beneficial for low-noise circuits.

Some embodiments may convert high voltage signals to capacitive signals. At low temperature, some circuits do not suffer as much FR losses. Utilization of capacitive coupling at low temperatures may allow some signals to travel longer distances without attenuation. Some embodiments of a CCD may be beneficially employed in high speed domino circuits with capacitive coupling, particularly for low temperature, low noise scenarios. At the front-end, capacitively coupling may provide better signal coupling. For example, a low temperature CCD may be utilized in a memory circuit as part of row decoder circuit (e.g., read domino driver) and/or a dynamic multiplexer circuit.

A data path may refer to any of a variety of functional units such as arithmetic logic units (ALUs), multipliers, etc. that perform data processing operations, as well registers, buses, etc. that support such data processing operations. In some systems, multiple data paths may be joined (e.g., with multiplexers) to form a larger data path. The width of the data path in bits may be highly relevant to a performance of a processor.

At low temperature, the thermal noise may be significantly reduced. With low thermal noise, there may be significantly fewer random disturbances that impact signal transfer. In particular, there may be significantly less crosstalk or other disturbances on the data path. In some applications, some metal lines may suffer from more signal disturbances because those signals are toggling between one and zero more than other signal lines. For example, the data path may include signal lines that toggle the most in an IC. In some embodiments, the data path may be where most of the processing happens, but data path signals may represent relatively few of the metal lines.

Generally, signal lines in the data path are directly connected (e.g., resistively coupled) to devices in the data path. Instead of resistively connecting all of the signal lines in an IC, some embodiments may capacitively couple selected signal lines. Resistive connections are associated with resistive-capacitive (RC) delays. By removing the resistive coupling connection, and instead utilizing capacitive coupling, the capacitive connection may be charged and discharged very quickly the total capacitance may be suitably limited. Signals and device terminals may be capacitively coupled either between two metal lines, between a metal line and a semiconductor (e.g., a degenerate semiconductor), or between the fins of the semiconductor in a transistor (e.g., a FinFET, a nanosheet transistor, etc.) and the gate of the transistor (e.g., that may be a metal). In some embodiments, metal layers may be positioned at different heights within an oxide layer for the purpose of inducing coupling or avoiding coupling. In some embodiments, high-k insulators may be positioned between metal layers for the purpose of inducing capacitively coupling.

Some embodiments of IC dies, systems, circuits, and techniques described herein are related to CCD devices for ultra-low voltage operation. Such CCD devices may be operable at very low temperatures for improved device performance and/or they may be integrated with complementary metal oxide semiconductor field effect transistors (CMOS FETs) such as FinFETs, nanosheet transistors, etc.

Techniques discussed herein provide advantageous CCD devices for low voltage applications. In some embodiments, such applications are deployed at very low temperatures, such as, at or below 0° C. For example, the CCD devices may be deployed in an IC die including or coupled to cooling structure operable to remove heat from the IC die to achieve an operating temperature at the very low temperature. As used herein, the term cooling structure or active cooling structure indicates a device that uses power to provide cooling (e.g., via flow of a coolant, immersion in a coolant, etc.). Notably, the cooling structure or active cooling structure need not be in operation to be labeled as such. The active cooling structure may be part of the IC die, provided separate from the IC die, or both. In some contexts, an active cooling structure is not needed as the IC die is deployed in a very low temperature environment such as in any of a subpolar oceanic climate, a subarctic climate, an arctic climate, a tundra climate, an ice cap climate, or any other environment of sustained cold temperatures.

In some embodiments, a CCD device includes capacitive coupling materials. At room temperatures, such materials exhibit thermal noise and unintended coupling behavior that significantly limits the utility of such materials in a CCD device. However, at very low temperatures, such materials exhibit much lower thermal noise characteristics. For example, at very low temperatures, a CCD device may be constructed with suitably selected capacitance materials so the device acts with only intended signal coupling behavior and may be deployed in a wide variety of useful circuits. Advantageously, some CCD devices may enable higher frequency circuits,

In deployment at very low temperatures, CCD devices using such materials systems have well controlled capacitive coupling behavior. Therefore, such CCD devices may advantageously be deployed as various circuits/devices including transistors, diodes, domino circuits, data path circuits, etc. In some embodiments, the CCD devices are used at very low voltage. In some implementations, the term very low voltage indicates a voltage of not more than 50 mV, although lower voltages may be used such as voltages of not more than 10 mV. In some embodiments, the CCD devices are integrated with CMOS FETs such as CMOS FinFETs, nanosheet transistors, etc. Notably, after fabrication of the CCD devices over a first substrate, the CCD devices may be layer transferred to a second substrate such as a silicon substrate and the CMOS FETs may be fabricated in an exposed portion of the silicon substrate either on the same side as the CCD devices or on an opposite side of the CCD devices. The CCD devices and CMOS FETs are then integrated into circuits that advantageously use both devices at very low temperature. For example, the CCD devices may be deployed as data path circuitry, etc., and the CMOS FETs may be deployed in other circuitry.

As discussed, an IC die including CCD devices and CMOS FETs may be deployed in a very low temperature context. In some embodiments, the operating temperature of the IC die is maintained at or below 0° C. In some embodiments, the operating temperature of the IC die is maintained at or below about −196° C. (i.e., using liquid nitrogen as the coolant). In some embodiments, the operating temperature of the IC die is maintained at or below about −25° C. In some embodiments, the operating temperature of the IC die is maintained at or below about −50° C. In some embodiments, the operating temperature of the IC die is maintained at or below about −70° C. In some embodiments, the IC die is maintained at or below about −100° C. Other temperatures may be used based on coolant, environment, and so on. Other temperatures may be used based on coolant, environment, and so on. In operation at such very low temperatures, the CCD devices become operable and the CMOS FETs see a substantial boost in performance relative to operation at higher temperatures inclusive of increased carrier mobility, reduced contact resistance, and reduced leakage.

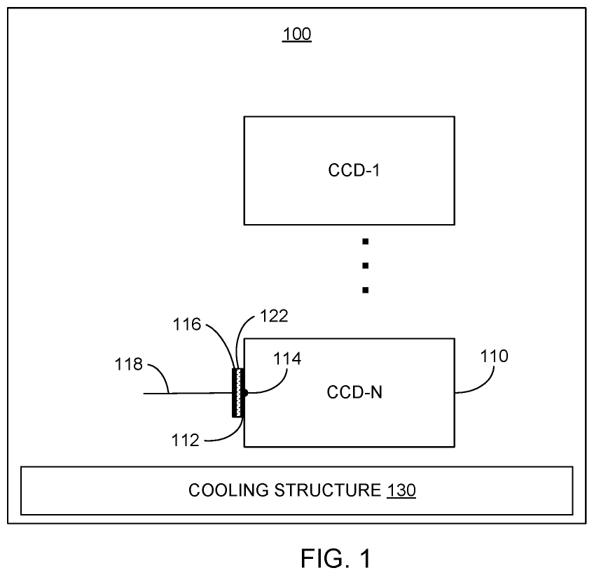

FIG. 1 shows an illustrative block diagram view of an example IC die 100 that includes one or more CCDs in accordance with some embodiments. The IC die 100 includes a first conductive structure 112 for a terminal 114 of a CCD 110, a second conductive structure 116 aligned with the first conductive structure 112 for a signal 118 to be capacitively coupled to the terminal 114 of the CCD 110, a first insulator material 122 disposed between the first conductive structure 112 and the second conductive structure 116, where the first insulator material 122 comprises high gain insulator material, and a cooling structure 130 operable to remove heat from the CCD 110 to achieve an operating temperature at or below 0° C.

The CCD 110 may be semiconductor or metal, and the amount of coupling may be determined by the dielectric constant, thickness, bandgap, area of overlap of the respective materials for the first conductive structure 112, the second conductive structure 116, and the first insulator material 122. In some embodiments, the first insulator material 122 may have a dielectric constant that is greater than three and nine tenths (e.g., k>3.9)

For some CCDs, the first conductive structure 112 and the second conductive structure 116 may be horizontally aligned. For some CCDs, the first conductive structure 112 and the second conductive structure 116 may be vertically aligned. In some embodiments, the IC die 100 may comprise front-side layers and back-side layers, and one or more CCDs may be in front-side layers of the IC die 100, back-side layers of the IC die 100, or both. The CCDs may be part of any useful circuit. For example, the CCD 110 may be part of a domino circuit. The signal 118 may be any signal line of the IC die 100. For example, the signal 118 may comprise a data path signal, such as a processor data bus signal.

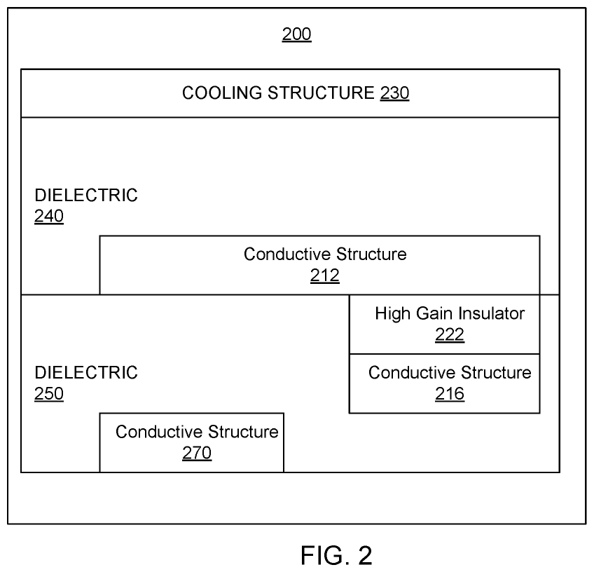

FIG. 2 shows an illustrative block diagram side view of an example IC die 200 that includes one or more CCDs in accordance with some embodiments. The IC die 200 includes a first conductive structure 212 for a terminal of a CCD (e.g., such as the CCD 110), a second conductive structure 216 aligned with the first conductive structure 212 for a signal to be capacitively coupled to the terminal of the CCD, a first insulator material 222 disposed between the first conductive structure 212 and the second conductive structure 216, where the first insulator material 222 comprises high gain insulator material, and a cooling structure 230 operable to remove heat from the IC die 200 to achieve an operating temperature at or below 0° C. The CCD may be semiconductor or metal, and the amount of coupling may be determined by the dielectric constant, thickness, bandgap, area of overlap of the respective materials for the first conductive structure 212, the second conductive structure 216, and the first insulator material 222.

In FIG. 2, the IC die 200 further includes a first dielectric layer 240 with the first conductive structure 212 embedded therein, and a second dielectric layer 250 vertically adjacent to the first dielectric layer 240 with the second conductive structure 216 embedded therein, where the second conductive structure 216 is vertically aligned with the first conductive structure 212. The first insulator material 222 has a horizontal orientation, with a longest side of the first insulator material 222 parallel to a layer orientation of the IC die 200. In some embodiments, one or more of the first conductive structure 212 and the second conductive structure 216 may comprise a metal material (e.g., a metallization structure). In some embodiments, one or more of the first conductive structure 212 and the second conductive structure 216 may comprise a degenerate semiconductor material (e.g., a highly doped semiconductor structure). In some embodiments, the high gain insulator material comprises a high-k oxide material (e.g., k>3.9). In some embodiments, the high gain insulator material comprises a high-k nitride material (e.g., k>3.9).

Some embodiments of the IC die 200 may further include second insulator material (e.g., the material of the second dielectric layer 250) in contact with the first conductive structure 212 and the second conductive structure 216, where the second insulator material may comprise lower gain insulator material (e.g., k=3.9 or less) as compared to the first insulator material 222. In some embodiments, the IC die 200 may further include a third conductive structure 270 in contact with the second insulator material (e.g., in the second dielectric layer 250), where the third conductive structure 270 is proximate to the first conductive structure 212 and vertically spaced further from the first conductive structure 212 as compared to the second conductive structure 216. For example, the closer distance and high gain material between the first conductive structure 212 and the second conductive structure 216 may promote capacitive coupling while the further distance and the lower gain material between the third conductive structure 270 and the first conductive structure 212 may inhibit capacitively coupling therebetween.

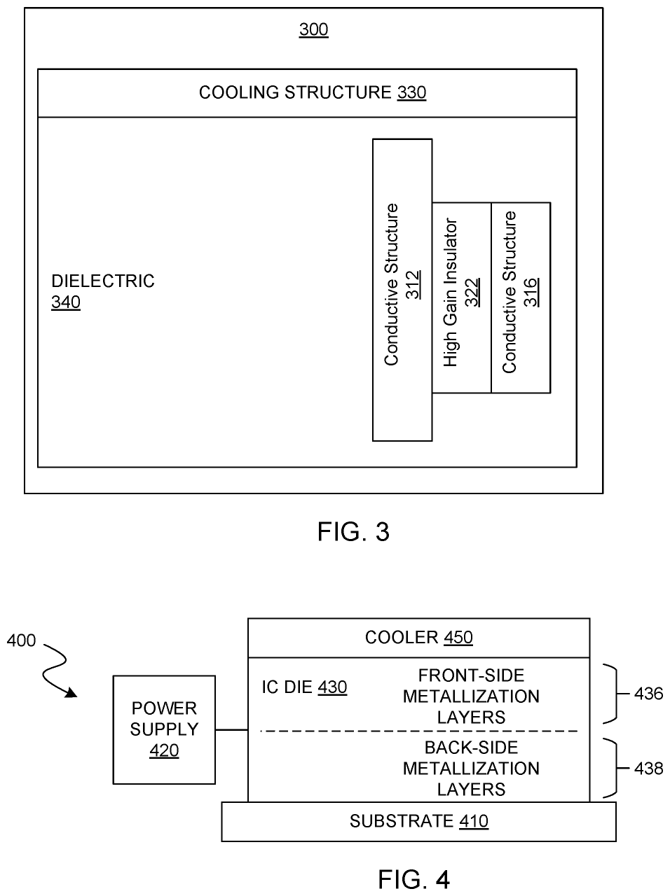

FIG. 3 shows an illustrative block diagram side view of an example IC die 300 that includes one or more CCDs in accordance with some embodiments. The IC die 300 includes a first conductive structure 312 for a terminal of a CCD (e.g., such as the CCD 110), a second conductive structure 316 aligned with the first conductive structure 312 for a signal to be capacitively coupled to the terminal of the CCD, a first insulator material 322 disposed between the first conductive structure 312 and the second conductive structure 316, where the first insulator material 322 comprises high gain insulator material, and a cooling structure 330 operable to remove heat from the IC die 300 to achieve an operating temperature at or below 0° C. The CCD may be semiconductor or metal, and the amount of coupling may be determined by the dielectric constant, thickness, bandgap, area of overlap of the respective materials for the first conductive structure 312, the second conductive structure 316, and the first insulator material 322.

In FIG. 3, the IC die 300 further includes one or more dielectric layers 340 with the first conductive structure 312 and the second conductive structure 316 embedded therein, where the second conductive structure 316 is horizontally aligned with the first conductive structure 312. The first insulator material 322 has a vertical orientation, with a longest side of the first insulator material 322 perpendicular to a layer orientation of the IC die 300. In some embodiments, one or more of the first conductive structure 312 and the second conductive structure 316 may comprise a metal material (e.g., a vertical metallization structure that spans multiple layers). In some embodiments, one or more of the first conductive structure 312 and the second conductive structure 316 may comprise a degenerate semiconductor material (e.g., a highly doped semiconductor structure). In some embodiments, the high gain insulator material comprises a high-k oxide material (e.g., k>3.9). In some embodiments, the high gain insulator material comprises a high-k nitride material (e.g., k>3.9).

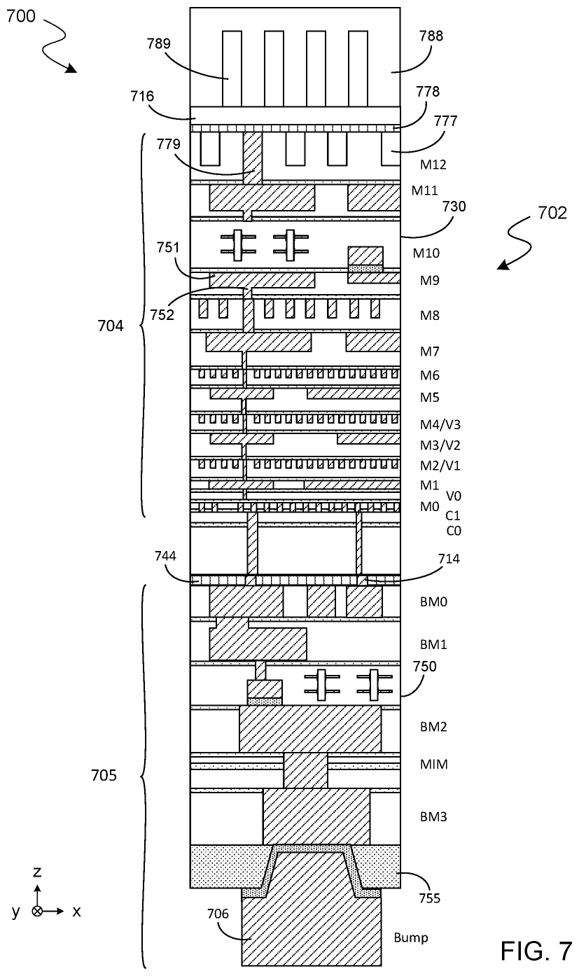

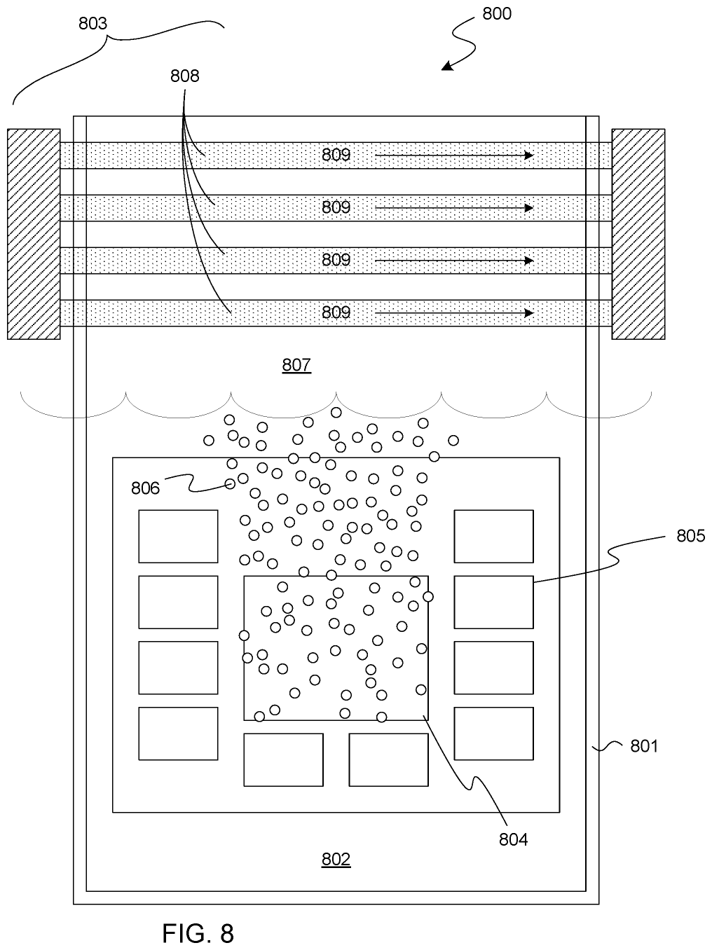

FIG. 4 shows a block diagram view of an example of a system 400 that includes a substrate 410, a power supply 420, and an IC die 430 attached to the substrate 410 and coupled to the power supply 420. The IC die 430 may be similarly configured as any of the various ICs described herein including, for example, the IC die 100 (FIG. 1), IC die 200 (FIG. 2), the IC die 300 (FIG. 3), the IC die 600 (FIG. 6), and IC die 702 (FIG. 7). Any suitable substrate technology may be utilized for the substrate 410 including, for example, the substrates described herein in connection with FIGS. 7 and 8 (e.g., substrate 805). In some embodiments, the IC die 430 may be coupled to the power supply 420 through the substrate 410.

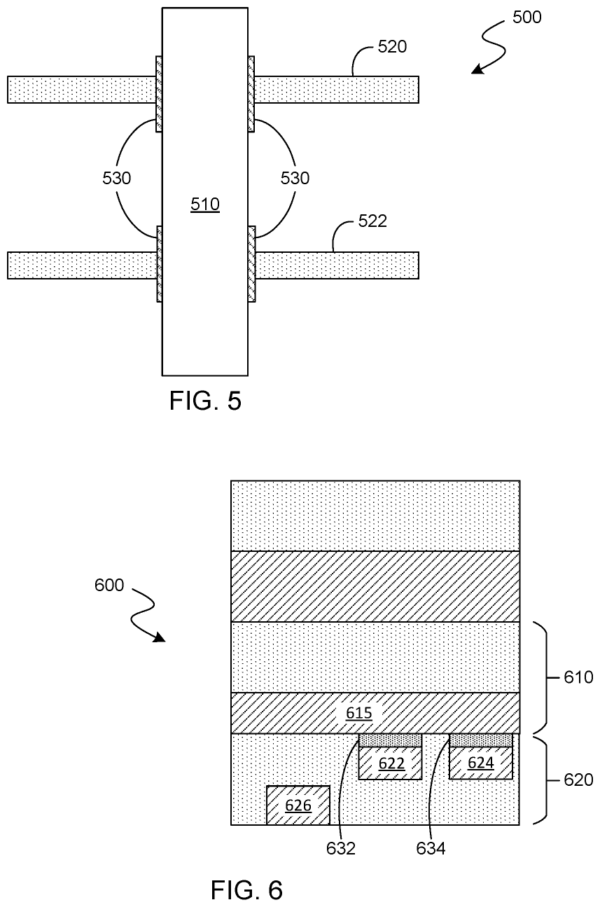

In some embodiments, the IC die 430 may include a plurality of CCD devices as described herein, wherein at least one CCD of the plurality of CCD devices comprises a first conductive structure (e.g., a metal or a degenerate semiconductor) for a terminal of the CCD, a second conductive structure (e.g., a metal or a degenerate semiconductor) horizontally or vertically aligned with the first conductive structure for a signal to be capacitively coupled to the terminal of the CCD, and a first insulator material (e.g., a high gain insulator material such as a high-k oxide, a high-k nitride, etc.) disposed between the first conductive structure and the second conductive structure. For example, the CCDs may be in front-side metallization layers 436 and/or back-side metallization layers 438 of the IC die 430 and may have vertical arrangements as shown in FIG. 2 and FIG. 6 and/or horizontal arrangements as shown in FIG. 3 and FIG. 5. The CCDs may be employed in any useful circuitry (e.g., domino circuits) and may capacitively couple to any useful signals (e.g., data path signals, processor data bus signals, etc.).

The system 400 further includes a cooler 450 thermally coupled to the IC die 430. In some embodiments, the cooler 450 provides a cooling structure operable to remove heat from the IC die to achieve an operating temperature at or below 0° C. For example, the IC die 430 may comprise a plurality of metallization layers over a front side of the plurality of CCD devices, the metallization layers to provide signal routing for the plurality of CCD devices, and the cooling structure 450 may be over the plurality of metallization layers. In some embodiments, the cooler 450 may comprise a plurality of microchannels in the IC die 430 and over the plurality of metallization layers, the microchannels to convey a heat transfer fluid therein. In some embodiments, the cooler 450 may further comprise a chiller mounted to the IC die 430 over the microchannels, the chiller comprising one of a solid body comprising second microchannels to convey a second heat transfer fluid therein or a heat sink for immersion in a low-boiling point liquid. In some embodiments, the cooler 450 may be operable to remove heat from the IC die to achieve an operating temperature at or below about −25° C. In some embodiments, the cooler 450 may be configured to convey liquid nitrogen to achieve an operating temperature at or below about −196° C.

FIG. 5 is a cross-sectional side view of a CCD 500 configured as a nanosheet transistor device according to an embodiment. The CCD 500 includes an all-around gate 510, a first fin 520 and a second fin 522. Gate oxide 530 material separates the fins 520, 522 from the gate 510, such that signals on the fins 520, 522 are capacitively coupled to the gate 510. For example, the fins 520, 522 may be any suitable semiconductor material and the gate 510 may be any suitable metal material (e.g., or a degenerately doped semiconductor material that acts similar to metal with similar capacitive coupling characteristics). The gate oxide 530 may be any suitable oxide including, for example, a high-k oxide (e.g., k>3.9). Any suitable techniques may be utilized to form, grow, or deposit the materials including, for example, atomic layer deposition (ALD), chemical vapor deposition (CVD), and plasma vapor deposition (PVD).

Signal to be coupled to the terminals of the CCD 500 may be capacitively coupled between the semiconductor material of the fins 520, 522 of the nanosheet transistor and the gate of the nanosheet transistor. The amount of coupling may be determined by the dielectric constant, thickness, bandgap, area of overlap of the respective materials for the fins 520, 522, the gate 510, and the gate oxide 530. Every time there is a toggle in the signal (e.g., from zero to one or from one to zero), there is a charge that is induced or discharged in the fins (e.g., depending on whether the toggle is from zero to one or one to zero). The charge acts as the signal on the terminals of the CCD 500 and a circuit with the CCD 500 is configured to utilize the charges going into the fins or out of the fins as a way of signaling that relies on toggles as opposed to static signals.

FIG. 6 is a cross-sectional side view of an example of an IC die 600 that includes capacitive coupling of signals for low temperature CCDs. A non-limiting example of a circuit that may beneficially utilize capacitive coupling includes a memory circuit that has a dynamic multiplexer that relies on capacitive coupling. The signal may go through the dynamic multiplexer and connect to a capacitor from where the signal may then couple onward. The capacitive coupling may help to reduce the overall capacitive load because the capacitor disconnects the initial part of the circuit from the remaining part of the circuit.

The IC die 600 includes multiple metal, semiconductor, and dielectric or insulator layers arranged to either induce or avoid capacitive coupling as desired for the various circuits and devices implemented in the IC die 600. As shown in FIG. 6, a first dielectric layer 610 includes a first metallization structure 615 embedded therein that may correspond to a first signal line or a terminal of a CCD. A second dielectric layer 620 includes a second metallization structure 622, a third metallization structure 624, and a fourth metallization structure 626 (e.g., that extends further into the page) embedded therein. In accordance with a circuit design, the second and third metallization structures 622 and 624 may correspond to second and third signal lines that are to be coupled to the first signal line or terminal of the CCD (e.g., through the first metallization structure 615), and the fourth metallization structure 626 may correspond to a fourth signal line that is not to be coupled to the first signal line or terminal of the CCD.

The IC die 600 further includes respective high gain (e.g., k>3.9) insulator material 632 and 634 formed between the first metallization structure 615 and the second and third metallization structures 622, 624 to induce capacitive coupling therebetween. The first and second dielectric layers 610, 620 may be formed from low gain (e.g., k=3.9 or less) insulator materials to avoid or inhibit coupling between the first metallization structure 615 and the fourth metallization structure 626. The fourth metallization structure 626 may further be formed with more vertical spacing from the first metallization structure 615 (e.g., as compared to the second and third metallization structures 622, 624) to further avoid or inhibit coupling between the first metallization structure 615 and the fourth metallization structure 626. With suitably selected materials and distances between the structures, the first metallization structure 615 will couple readily to the second and third metallization structures 622, 624, but the first metallization structure 615 will not couple to the fourth metallization structure 626.

Any suitable techniques may be utilized to form, grow, or deposit the materials including, for example, ALD, CVD, and PVD. The CCD may be semiconductor or metal, and the amount of coupling may be determined by the dielectric constant, thickness, bandgap, area of overlap of the respective materials for the first metallization structure 615, the second and third metallization structures 622, 624, and the high gain insulator materials 632, 634.

Those skilled in the art will appreciate that embodiments may be applied to more complicated interconnect networks with suitably selected materials and distances between the structures to induce or avoid capacitive coupling as needed for a large number and wide variety of signals, devices, and circuits. While such extensive capacitive coupling throughout an IC die may be problematic at room temperature because of noise, at low temperature much of the noise is effectively screened out and embodiments may advantageously make more extensive use of capacitively coupled devices, particularly for data path signals and circuits.

In some embodiments, ICs with CCDs as described herein may be integrated into a low-temperature system. Lower temperatures enhance conduction in many materials and can enable the use of, e.g., different materials and structures (such as smaller transistor channels). A number of structures may be used to lower the system temperature and so allow for the use of, e.g., smaller conducting structures. Active cooling structures can be used to lower system temperatures to below ambient temperature, even to well below ambient temperature. Active cooling structures can include thermoelectric coolers. In some embodiments, active cooling structures include stacks of alternating p- and n-type semiconductor materials. In some embodiments, active cooling structures flow cooling fluids through channels, including microchannels, thermally coupled to IC packages. In some embodiments, active cooling structures include channels thermally coupled to IC dies 100, 200, 300, 430, 600, 702. In some embodiments, active cooling structures include channels on one or more sides of IC dies 100, 200, 300, 430, 600, 702. In some embodiments, active cooling structures include channels within IC dies 100, 200, 300, 430, 600, 702. In some embodiments, active cooling structures include two-phase cooling. In some embodiments, active cooling structures include low-boiling-point fluids. In some embodiments, active cooling structures include refrigerants as cooling fluids. In some embodiments, active cooling structures lower system temperatures to below 0° C.

FIG. 7 illustrates a cross-sectional view of a low-temperature IC system 700 using die- and package-level active cooling, that includes CCDs in accordance with some embodiments. In the example of IC system 700, IC die 702 includes active-cooling structures or components as provided by both die-level microchannels 777 and package-level active-cooling structure 788. IC system 700 includes a lateral surface along the x-y plane that may be defined or taken at any vertical position of IC system 700. The lateral surface of the x-y plane is orthogonal to a vertical or build-up dimension as defined by the z-axis. In some embodiments, IC system 700 may be formed from any substrate material suitable for the fabrication of transistor circuitry. In some embodiments, a semiconductor substrate is used to manufacture CCDs and other transistors and components of IC system 700. The semiconductor substrate may include a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 7, IC system 700 includes an IC die 702, which is a monolithic IC with CCDs as described herein, including front-side metallization layers 704 (or front-side interconnect layers), and optional back-side metallization layers 705 (or back-side interconnect layers). As shown, IC die 702 may include CCDs embedded within front-side layers 730 and/or back-side layers 750 (the detailed structure of the CCDs is omitted from the cross-section of FIG. 7 to avoid obscuring the figure). In some embodiments, front-side metallization layers 704 (including further CCDs) provide signal routing to the non-planar transistors and back-side metallization layers 705 provide power delivery, as enabled by through-contacts 714, and vias. In some embodiments, IC system 700 further includes a package-level cooling structure 788, which may be deployed on or over front-side metallization layers 704 (as shown) or on or over a back-side of IC die 702. In some embodiments, package-level cooling structure 788 is coupled to IC die 702 by an adhesion layer 716. IC system 700 may also be deployed without back-side metallization layers 705 shown in FIG. 7. In such embodiments, signal routing and power are provided to circuits of the IC die 702 via front-side metallization layers 704. However, use of back-side metallization layers 705 may offer advantages.

The circuits of the IC die 702 are connected and thermally coupled by metallization, e.g., metal heat spreader 744, to the entire metallization structure by through-contacts 714. In this way, circuits of the IC die 702 are thermally coupled to both the die-level active-cooling structures (of die-level microchannels 777) and package-level active-cooling structure 788.

Interconnectivity of transistors, signal routing to and from circuitry of the IC die 702, metallization interconnects 751, vias 752 (e.g., and other vias), etc., power delivery to circuitry of the IC die 702, etc., and routing to an outside device (not shown), is provided by front-side metallization layers 704, optional back-side metallization layers 705, and package-level interconnects 706. In the example of FIG. 7, package-level interconnects 706 are provided on or over a back-side of IC die 702 as bumps over a passivation layer 755, and IC system 700 is attached to a substrate (and coupled to signal routing to, power delivery, etc.) by package-level interconnects 706. However, package-level interconnects 706 may be provided using any suitable interconnect structures such as bond pads, solder bumps, etc. Furthermore, in some embodiments, package-level interconnects 706 are provided on or over a front-side of IC die 702 (i.e., over front-side metallization layers 704) and package-level cooling structure 788 is provided on or over a back-side of IC die 702.

In IC system 700, IC die 702 includes die-level, active-cooling as provided by die-level microchannels 777. Die-level microchannels 777 are to convey a heat transfer fluid therein to remove heat from IC die 702. The heat transfer fluid may be any suitable liquid or gas. In some embodiments, the heat transfer fluid is liquid nitrogen operable to lower the temperature of IC die 702 to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane.

As used herein, the term “microchannels” indicates a channel to convey a heat transfer fluid with the multiple microchannels providing discrete separate channels or a network of channels. Notably, the plural microchannels does not indicate separate channel networks are needed. Such die-level microchannels 777 may be provided in any pattern in the x-y plane such as serpentine patterns, patterns of multiple parallel die-level microchannels 777, or the like. Die-level microchannels 777 couple to a heat exchanger (not shown) that removes heat from and cools the heat transfer fluid before re-introduction to die-level microchannels 777. The flow of fluid within die-level microchannels 777 may be provided by a pump or other fluid flow device. The operation of the heat exchanger, pump, etc. may be controlled by a controller.

In the illustrated embodiment, die-level microchannels 777 are implemented at metallization level M12. In other embodiments, die-level microchannels 777 are implemented over metallization level M12. Die-level microchannels 777 may be formed using any suitable technique or techniques such as patterning and etch techniques to form the void structures of die-level microchannels 777 and passivation or deposition techniques to form a cover structure 778 to enclose the void structures. As shown, in some embodiments, the die-level, active-cooling structure of IC system 700 includes a number of die-level microchannels 777 in IC die 702 and over a number of front-side metallization layers 704. As discussed, die-level microchannels 777 are to convey a heat transfer fluid therein. In some embodiments, a metallization feature 779 of metallization layer M12 is laterally adjacent to die-level microchannels 777. For example, metallization feature 779 may couple to a package-level interconnect structure (not shown) for signal routing for IC die 702. In some embodiments, a passive heat removal device such as a heat sink or the like may be used instead of or in addition to package-level cooling structure 788. In some embodiments, package-level cooling structure 788 is not deployed in IC system 700.

As used herein, the term “metallization layer” describes layers with interconnections or wires that provide electrical routing, generally formed of metal or other electrically and thermally conductive material. Adjacent metallization layers may be formed of different materials and by different methods. Adjacent metallization layers, such as metallization interconnects 751, are interconnected by vias, such as vias 752, that may be characterized as part of the metallization layers or between the metallization layers. As shown, in some embodiments, front-side metallization layers 704 are formed over and immediately adjacent transistors. The back-side is then the opposite side, which may be exposed during processing by attaching the front-side to a carrier wafer and exposing the back-side (e.g., by back-side grind or etch operations) as known in the art.

In the illustrated example, front-side metallization layers 704 include M0, V0, M1, M2/V1, M3/V2, M4/V3, and M4-M12. However, front-side metallization layers 704 may include any number of metallization layers such as eight or more metallization layers. Similarly, back-side metallization layers 705 include BM0, BM1, BM2, and BM3. However, back-side metallization layers 705 may include any number of metallization layers such as two to five metallization layers. Front-side metallization layers 704 and back-side metallization layers 705 are embedded within dielectric materials. Furthermore, optional metal-insulator-metal (MIM) devices such as diode devices may be provided within back-side metallization layers 705. Other devices such as capacitive memory devices may be provided within front-side metallization layers 704 and/or back-side metallization layers 705.

IC system 700 includes package-level active-cooling structure 788 having package-level microchannels 789. Package-level microchannels 789 are to convey a heat transfer fluid therein to remove heat from IC die 702. The heat transfer fluid may be any suitable liquid or gas as discussed with respect to die-level microchannels 777. Package-level microchannels 789 may be provided in any pattern in the x-y plane such as serpentine patterns, patterns of multiple parallel package-level microchannels 789, etc. Package-level microchannels 789 couple to a heat exchanger (not shown) that removes heat from and cools the heat transfer fluid before re-introduction to package-level microchannels 789. The flow of fluid within package-level microchannels 789 may be provided by a pump or other fluid-flow device. The operation of the heat exchanger, pump, etc. may be controlled by a controller. In the illustrated embodiment, package-level active-cooling structure 788 is a chiller mounted to IC die 702 such that the chiller has a solid body having microchannels therein to convey a heat transfer fluid.

In some embodiments, the heat-removal fluid deployed in die-level microchannels 777 and package-level active-cooling structure 788 are coupled to the same pump and heat exchanger systems. In such embodiments, the heat removal fluid conveyed in both die-level microchannels 777 and package-level active-cooling structure 788 are the same material. Such embodiments may advantageously provide simplicity. In other embodiments, the heat removal fluids are controlled separately. In such embodiments, the heat removal fluids conveyed by die-level microchannels 777 and package-level active-cooling structure 788 may be the same or they may be different. Such embodiments may advantageously provide improved flexibility.

As discussed, IC system 700 includes IC die 702 and optional die-level and package-level active-cooling structures operable to remove heat from IC die 702 to achieve a very low operating temperature of IC die 702. As used herein, the term “very low operating temperature” indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. may be used. In some embodiments, the operating temperature is in a cryogenic temperature operating window (e.g., about −180° C. to about −70° C.). The active-cooling structure may be provided as a package-level structure (i.e., separable from IC die 702), as a die-level structure (i.e., integral to IC die 702), or both. In some embodiments, IC die 702 is deployed in a cold environment, formed using sufficiently conductive materials, etc. and an active-cooling structure is not used.

FIG. 8 illustrates a view of an example two-phase immersion cooling system 800 for low-temperature operation of an IC die, in accordance with some embodiments. As shown, two-phase immersion cooling system 800 includes a fluid containment structure 801, a low-boiling point liquid 802 within fluid containment structure 801, and a condensation structure 803 at least partially within fluid containment structure 801. As used herein, the term “low-boiling point liquid” indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 804, such as an IC package including any of IC dies or systems 100, 200, 300, 400, 600, 700 as discussed herein is immersed in low-boiling point liquid 802. In some embodiments, IC dies or systems 100, 200, 300, 400, 600, 700 as deployed in two-phase immersion cooling system 800 do not include additional active cooling structures, although such die-level or package-level active cooling structures may be used in concert with two-phase immersion cooling system 800. In some embodiments, when deployed in two-phase immersion cooling system 800, package-level active-cooling structure 788 is a heat sink, a heat dissipation plate, a porous heat dissipation plate or the like.

Notably, IC die 702 (or IC die 100, 200, 300, 430, 600), is the source of heat in the context of two-phase immersion cooling system 800. For example, IC die 702 may be packaged and mounted on electronics substrate 805. Electronic substrate 805 may be coupled to a power supply (not shown) and may be partially or completely submerged in low-boiling point liquid 802.

In operation, the heat produced by heat generation source 804 vaporizes low-boiling point liquid 802 as shown in vapor or gas state as bubbles 806, which may collect, due to gravitational forces, above low-boiling point liquid 802 as a vapor portion 807 within fluid containment structure 801. Condensation structure 803 may extend through vapor portion 807. In some embodiments, condensation structure 803 is a heat exchanger having a number of tubes 808 with a cooling fluid (i.e., a fluid colder than the condensation point of vapor portion 807) shown by arrows 809 that may flow through tubes 808 to condense vapor portion 807 back to low-boiling point liquid 802. In the IC system of FIG. 8, package-level active-cooling structure 788 includes a passive cooling structure such as a heat sink for immersion in low-boiling point liquid 802.

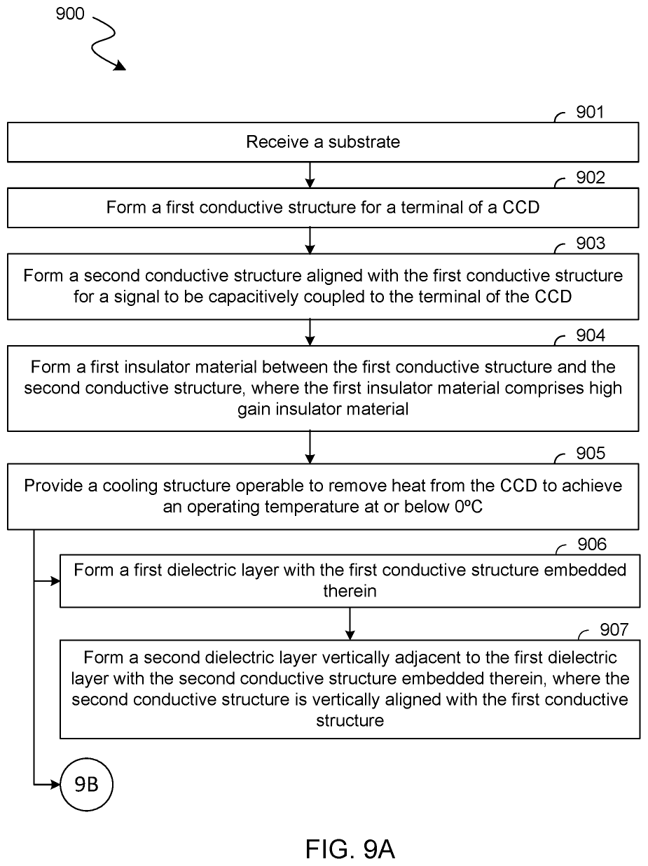

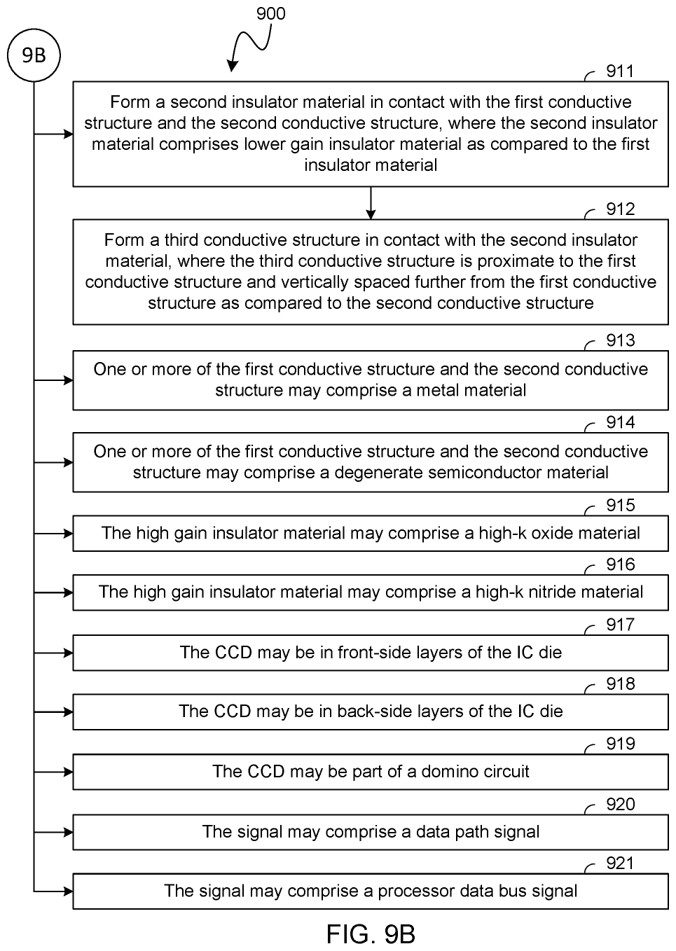

FIGS. 9A to 9B illustrate various processes or methods 900 for forming CCDs on an IC die, in accordance with some embodiments. FIGS. 9A to 9B show methods 900 that includes operations 901-914. Some operations shown in FIGS. 9A to 9B are optional. FIGS. 9A to 9B show an example sequence, but the operations can be done in other sequences as well, and some operations may be omitted. Some operations can also be performed multiple times before other operations are performed. Some operations may be included within other operations. Methods 900 generally entail forming high gain insulator material between two suitably spaced conductive structures, to capacitively couple devices/signals at low temperature.

In operation 901, a substrate is received. The substrate is a planar platform and may already include dielectric and metallization structures. The substrate may be one of many layers in an IC die, and may itself have many layers. The substrate may be above other layers in the IC die (all or of a portion of which may be subsequently removed in back-side metallization contexts), and other layers may subsequently be formed in or over the substrate. In some embodiments, CCDs will be formed on a frontside of the substrate. In some embodiments, CCDs will be formed on a backside. In some embodiments, CCDs will be formed on both sides.

The substrate may include any suitable material or materials. Any suitable semiconductor or other material can be used. Transistors in the IC die may be of the same material as the substrate or, e.g., deposited on the substrate. The substrate may include a semiconductor material that transistors can be formed out of and on, including a crystalline material. In some examples, the substrate may include monocrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, the substrate includes crystalline silicon and subsequent components are also silicon.

In operation 902, a first conductive structure is formed for a terminal of a CCD. For example, the first conductive structure may be formed in a first metallization layer. The first metallization layer need not be formed before, e.g., other layers of the IC die. Forming the first metallization layer and other layers of the IC die may include forming transistors, resistors, and interconnections, e.g., between them and with external structures, including power, signal, data, ground, etc. lines. At least some of these structures may be conventional and known methods may be used.

Transistors in the IC die can be formed from the same material as the substrate or, e.g., deposited on the substrate. In some embodiments, the substrate is crystalline silicon and transistors in the first layer are formed by etching back the substrate to form transistor structures, e.g., non-planar structures, such as fins for access transistor channels. In some embodiments, transistors comprise polycrystalline silicon, which may be deposited over other materials. Other semiconductor materials may be deposited as well, on the substrate or over other structures on the substrate. Such semiconductor materials can be any material suitable for forming a transistor channel, e.g., for an access transistor, but some materials will be preferred for their manufacturing properties, e.g., the capability to be deposited easily, in a well-controlled manner, and in thin layers.

Forming the transistors may include forming ultrathin structures, such as nanowires, nanoribbons, or nanosheets, for transistor channels. In some embodiments, one or a few monolayers of semiconductor materials are deposited over the substrate or other structures. In some embodiments, less than 2 nm of semiconductor material is deposited as a film. In some embodiments, a transition-metal dichalcogenide (TMD) material is deposited to form access transistors. TMDs can be 2D materials, e.g., forming monolayers of semiconductor materials. 2D materials may be deposited on structures, such as backbone features, deposited on the substrate.

The methods for forming transistors may vary with transistor function. TFTs for use as pull-up transistors may be formed as parasitic devices deposited over other structures in some layers. In some embodiments, forming transistors includes depositing amorphous or polycrystalline metal oxides. In some embodiments, a thin, metal-oxide film is deposited that may be semiconducting substantially as-deposited, and/or following some subsequent activation process, such as a thermal anneal.

Other structures, e.g., resistors and metallization, may also be deposited or otherwise formed from such materials, and such forming may be done throughout the forming operations of transistors and other structures. Pull-up resistors may be formed from the substrate material or, e.g., by depositing polycrystalline silicon or other material over the substrate. Other structures, e.g., access transistor gate electrodes, may be formed such that convenient connections can be made to associated structures in the first layer. Metallization may be formed before and after, and interleaved throughout, the forming of other structures.

In operation 903, a second conductive structure is formed aligned with the first conductive structure for a signal to be capacitively coupled to the terminal of the CCD. For example, the second conductive structure may be formed in a second metallization layer. The second metallization layer need not be formed before, e.g., other layers of the IC die. Forming the second metallization layer and other layers of the IC die may include forming transistors, resistors, and interconnections, e.g., between them and with external structures, including power, signal, data, ground, etc. lines. At least some of these structures may be conventional and known methods may be used.

In operation 904, a first insulator material is formed between the first conductive structure and the second conductive structure, where the first insulator material comprises high gain insulator material. In operation 905, a cooling structure is provided operable to remove heat from the CCD to achieve an operating temperature at or below 0° C.

In operations 906 and 907, a first dielectric layer is formed with the first conductive structure embedded therein, and a second dielectric layer is formed vertically adjacent to the first dielectric layer with the second conductive structure embedded therein, where the second conductive structure is vertically aligned with the first conductive structure.

In operation 911, a second insulator material is formed in contact with the first conductive structure and the second conductive structure, where the second insulator material comprises lower gain insulator material as compared to the first insulator material. In operation 912, a third conductive structure is formed in contact with the second insulator material, where the third conductive structure is proximate to the first conductive structure and vertically spaced further from the first conductive structure as compared to the second conductive structure.

In box 913, one or more of the first conductive structure and the second conductive structure may comprise a metal material. In box 914, one or more of the first conductive structure and the second conductive structure may comprise a degenerate semiconductor material. In box 915, the high gain insulator material may comprise a high-k oxide material (e.g., k>3.9). In box 916, the high gain insulator material may comprise a high-k nitride material (e.g., k>3.9). In box 917, the CCD may be in front-side layers of the IC die. In box 918, the CCD may be in back-side layers of the IC die. In box 919, the CCD may be part of a domino circuit. In box 920, the signal may comprise a data path signal. In box 921, the signal may comprise a processor data bus signal.

In some embodiments, two circuits or signals (and more) are formed in vertically adjacent layers where in different metallization layers are connected between layers by forming a vertical metallization structure, e.g., a metallized via connection, on one side of the layers, beyond the horizontal edges or boundaries of the circuits. In some such embodiments, a deep border via connects the different metallization layers. In some embodiments, two of these connected circuits are vertically aligned, and other connected circuits in both layers are not vertically aligned. The vertical metallization structure, e.g., a via, can be formed as part of traditional or other methods, e.g. single or dual damascene techniques, etc.

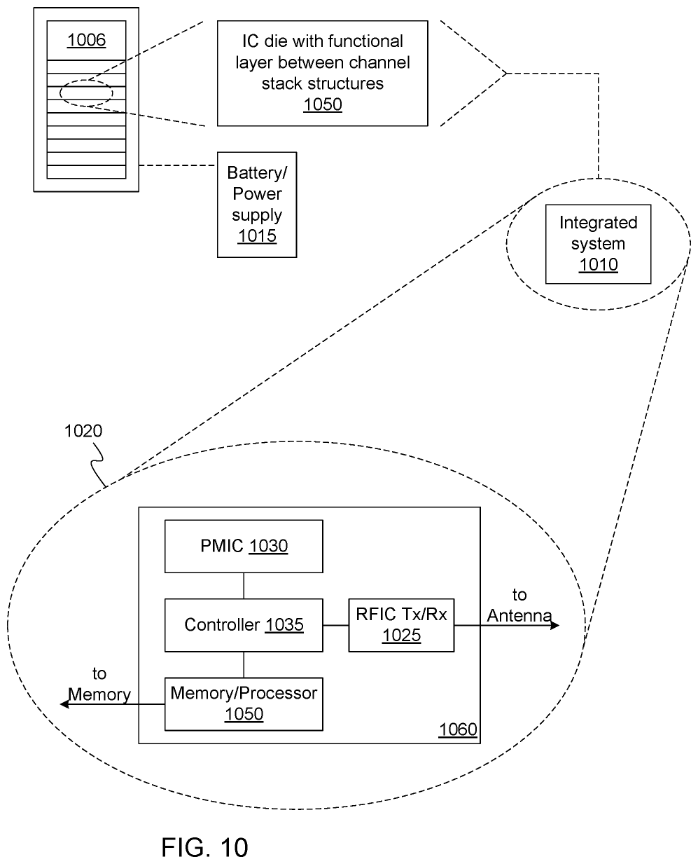

FIG. 10 illustrates a diagram of an example data server machine 1006 employing an IC die with CCDs as described herein, in accordance with some embodiments. Server machine 1006 may be any commercial server, for example, including any number of high-performance computing platforms disposed within a rack and networked together for electronic data processing, which in the exemplary embodiment includes one or more devices 1050 having CCDs.

Also as shown, server machine 1006 includes a battery and/or power supply 1015 to provide power to devices 1050, and to provide, in some embodiments, power delivery functions such as power regulation. Devices 1050 may be deployed as part of a package-level integrated system 1010. Integrated system 1010 is further illustrated in the expanded view 1020. In the exemplary embodiment, devices 1050 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 1050 is a microprocessor including a cache memory. As shown, device 1050 may be a multi-chip module employing one or more IC dies with CCDs, as discussed herein. Device 1050 may be further coupled to (e.g., communicatively coupled to) a board, an interposer, or a substrate 1060 along with, one or more of a power management IC (PMIC) 1030, RF (wireless) IC (RFIC) 1025, including a wideband RF (wireless) transmitter and/or receiver (TX/RX) (e.g., including a digital baseband and an analog front end module further comprises a power amplifier on a transmit path and a low noise amplifier on a receive path), and a controller 1035 thereof. In some embodiments, RFIC 1025, PMIC 1030, controller 1035, and device 1050 include IC dies having CCDs on substrate 1060 in a multi-chip module.

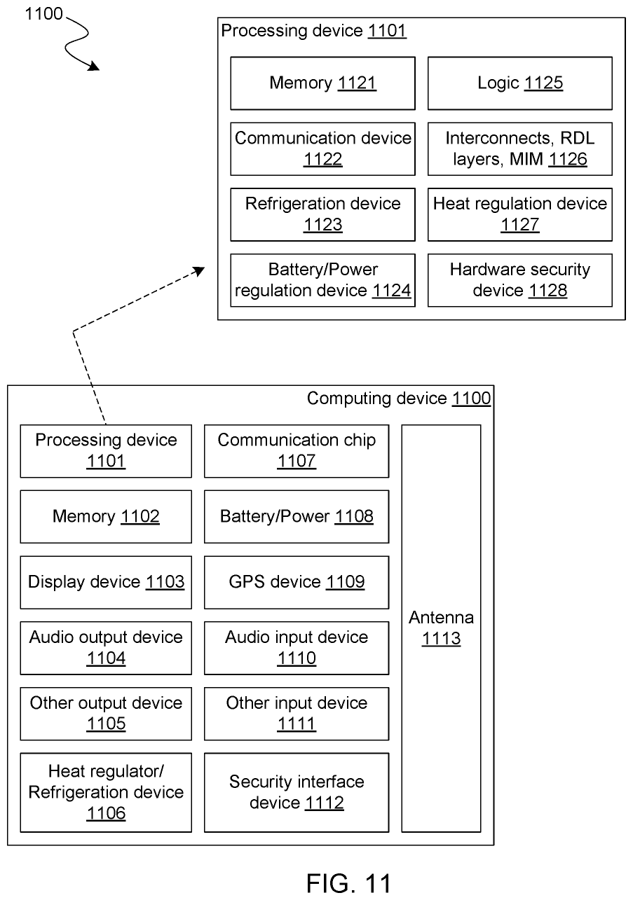

FIG. 11 is a block diagram of an example computing device 1100, in accordance with some embodiments. For example, one or more components of computing device 1100 may include any of the devices or structures discussed herein. A number of components are illustrated in FIG. 11 as being included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121, a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1102 includes memory that shares a die with processing device 1101. This memory may be used as cache memory and may include embedded dynamic random-access memory (eDRAM) or spin transfer torque magnetic random-access memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-11. The subject matter may be applied to other deposition applications, as well as any appropriate manufacturing application, as will be understood to those skilled in the art.

The following examples pertain to further embodiments, and specifics in the examples may be used anywhere in one or more embodiments.

Example 1 includes an integrated circuit (IC) die, comprising a first conductive structure for a terminal of a capacitively coupled device, a second conductive structure aligned with the first conductive structure for a signal to be capacitively coupled to the terminal of the capacitively coupled device, a first insulator material disposed between the first conductive structure and the second conductive structure, wherein the first insulator material comprises high gain insulator material, and a cooling structure operable to remove heat from the capacitively coupled device to achieve an operating temperature at or below 0° C.

Example 2 includes the IC die of Example 1, further comprising a first dielectric layer with the first conductive structure embedded therein, and a second dielectric layer vertically adjacent to the first dielectric layer with the second conductive structure embedded therein, wherein the second conductive structure is vertically aligned with the first conductive structure.

Example 3 includes the IC die of any of Examples 1 to 2, wherein one or more of the first conductive structure and the second conductive structure comprises a metal material.

Example 4 includes the IC die of any of Examples 1 to 2, wherein one or more of the first conductive structure and the second conductive structure comprises a degenerate semiconductor material.

Example 5 includes the IC die of any of Examples 1 to 4, wherein the high gain insulator material comprises a high-k oxide material.

Example 6 includes the IC die of any of Examples 1 to 4, wherein the high gain insulator material comprises a high-k nitride material.

Example 7 includes the IC die of any of Examples 1 to 6, further comprising second insulator material in contact with the first conductive structure and the second conductive structure, wherein the second insulator material comprises lower gain insulator material as compared to the first insulator material.

Example 8 includes the IC die of Example 7, further comprising a third conductive structure in contact with the second insulator material, wherein the third conductive structure is proximate to the first conductive structure and vertically spaced further from the first conductive structure as compared to the second conductive structure.

Example 9 includes the IC die of any of Examples 1 to 8, wherein the capacitively coupled device is in front-side layers of the IC die.

Example 10 includes the IC die of any of Examples 1 to 8, wherein the capacitively coupled device is in back-side layers of the IC die.

Example 11 includes the IC die of any of Examples 1 to 10, wherein the capacitively coupled device is part of a domino circuit.

Example 12, The IC die of any of Examples 1 to 11, wherein the signal comprises a data path signal.

Example 13 includes the IC die of any of Examples 1 to 11, wherein the signal comprises a processor data bus signal.

Example 14 includes a system, comprising a substrate, a power supply, an integrated circuit (IC) die attached to the substrate and coupled to the power supply, the IC die comprising a first conductive structure for a terminal of a capacitively coupled device, a second conductive structure aligned with the first conductive structure for a signal to be capacitively coupled to the terminal of the capacitively coupled device, and a first insulator material disposed between the first conductive structure and the second conductive structure, wherein the first insulator material comprises high gain insulator material, and a cooling structure operable to remove heat from the IC die to achieve an operating temperature at or below 0° C.

Example 15 includes the system of Example 14, wherein the IC die further comprises a first dielectric layer with the first conductive structure embedded therein, and a second dielectric layer vertically adjacent to the first dielectric layer with the second conductive structure embedded therein, wherein the second conductive structure is vertically aligned with the first conductive structure.

Example 16 includes the system of any of Examples 14 to 15, wherein one or more of the first conductive structure and the second conductive structure comprises a metal material.

Example 17 includes the system of any of Examples 14 to 15, wherein one or more of the first conductive structure and the second conductive structure comprises a degenerate semiconductor material.

Example 18 includes the system of any of Examples 14 to 17, wherein the high gain insulator material comprises one of a high k oxide material and a high-k nitride material.

Example 19 includes the system of any of Examples 14 to 18, further comprising second insulator material in contact with the first conductive structure and the second conductive structure, wherein the second insulator material comprises lower gain insulator material as compared to the first insulator material.

Example 20 includes the system of Example 19, further comprising a third conductive structure in contact with the second insulator material, wherein the third conductive structure is proximate to the first conductive structure and vertically spaced further from the first conductive structure as compared to the second conductive structure.

Example 21 includes the system of any of Examples 14 to 20, wherein the capacitively coupled device is in one of front-side and back-side layers of the IC die.

Example 22 includes the system of any of Examples 14 to 21, wherein the capacitively coupled device is part of a domino circuit.

Example 23 includes the system of any of Examples 14 to 22, wherein the signal comprises one of a data path signal and a processor data bus signal.

Example 24 includes the system of any of Examples 14 to 23, wherein the cooling structure is further operable to remove heat from the IC die to achieve an operating temperature at or below −25° C.

Example 25 includes the system of any of Examples 14 to 24, wherein the IC die comprises a plurality of metallization layers over a front side of the plurality of capacitively coupled devices, the metallization layers to provide signal routing for the plurality of capacitively coupled devices, and wherein the cooling structure is over the plurality of metallization layers.

Example 26 includes the system of Example 25, wherein the cooling structure comprises a plurality of microchannels in the IC die and over the plurality of metallization layers, the microchannels to convey a heat transfer fluid therein.

Example 27 includes the system of Example 26, wherein the cooling structure further comprises a chiller mounted to the IC die over the microchannels, the chiller comprising one of a solid body comprising second microchannels to convey a second heat transfer fluid therein or a heat sink for immersion in a low-boiling point liquid.

Example 28 includes the system of any of Examples 26 to 27, wherein the cooling structure is further to convey liquid nitrogen to achieve an operating temperature at or below about −196° C.

Example 29 includes a method, comprising receiving a substrate, forming a first conductive structure for a terminal of a capacitively coupled device, forming a second conductive structure aligned with the first conductive structure for a signal to be capacitively coupled to the terminal of the capacitively coupled device, forming a first insulator material between the first conductive structure and the second conductive structure, wherein the first insulator material comprises high gain insulator material, and providing a cooling structure operable to remove heat from the capacitively coupled device to achieve an operating temperature at or below 0° C.

Example 30 includes the method of Example 29, further comprising forming a first dielectric layer with the first conductive structure embedded therein, and forming a second dielectric layer vertically adjacent to the first dielectric layer with the second conductive structure embedded therein, wherein the second conductive structure is vertically aligned with the first conductive structure.

Example 31 includes the method of any of Examples 29 to 30, wherein one or more of the first conductive structure and the second conductive structure comprises a metal material.

Example 32 includes the method of any of Examples 29 to 30, wherein one or more of the first conductive structure and the second conductive structure comprises a degenerate semiconductor material.

Example 33 includes the method of any of Examples 29 to 32, wherein the high gain insulator material comprises a high-k oxide material.

Example 34 includes the method of any of Examples 29 to 32, wherein the high gain insulator material comprises a high-k nitride material.

Example 35 includes the method of any of Examples 29 to 34, further comprising forming a second insulator material in contact with the first conductive structure and the second conductive structure, wherein the second insulator material comprises lower gain insulator material as compared to the first insulator material.

Example 36 includes the method of Example 35, further comprising forming a third conductive structure in contact with the second insulator material, wherein the third conductive structure is proximate to the first conductive structure and vertically spaced further from the first conductive structure as compared to the second conductive structure.

Example 37 includes the method of any of Examples 29 to 36, wherein the capacitively coupled device is in front-side layers of the IC die.

Example 38 includes the method of any of Examples 29 to 36, wherein the capacitively coupled device is in back-side layers of the IC die.

Example 39 includes the method of any of Examples 29 to 38, wherein the capacitively coupled device is part of a domino circuit.

Example 40 includes the method of any of Examples 29 to 39, wherein the signal comprises a data path signal.

Example 41 includes the method of any of Examples 29 to 39, wherein the signal comprises a processor data bus signal.

Example 42 includes an apparatus, comprising means for receiving a substrate, means for forming a first conductive structure for a terminal of a capacitively coupled device, means for forming a second conductive structure aligned with the first conductive structure for a signal to be capacitively coupled to the terminal of the capacitively coupled device, means for forming a first insulator material between the first conductive structure and the second conductive structure, wherein the first insulator material comprises high gain insulator material, and means for providing a cooling structure operable to remove heat from the capacitively coupled device to achieve an operating temperature at or below 0° C.

Example 43 includes the apparatus of Example 42, further comprising means for forming a first dielectric layer with the first conductive structure embedded therein, and means for forming a second dielectric layer vertically adjacent to the first dielectric layer with the second conductive structure embedded therein, wherein the second conductive structure is vertically aligned with the first conductive structure.

Example 44 includes the apparatus of any of Examples 42 to 43, wherein one or more of the first conductive structure and the second conductive structure comprises a metal material.

Example 45 includes the apparatus of any of Examples 42 to 43, wherein one or more of the first conductive structure and the second conductive structure comprises a degenerate semiconductor material.

Example 46 includes the apparatus of any of Examples 42 to 45, wherein the high gain insulator material comprises a high-k oxide material.

Example 47 includes the apparatus of any of Examples 42 to 45, wherein the high gain insulator material comprises a high-k nitride material.

Example 48 includes the apparatus of any of Examples 42 to 47, further comprising means for forming a second insulator material in contact with the first conductive structure and the second conductive structure, wherein the second insulator material comprises lower gain insulator material as compared to the first insulator material.

Example 49 includes the apparatus of Example 48, further comprising means for forming a third conductive structure in contact with the second insulator material, wherein the third conductive structure is proximate to the first conductive structure and vertically spaced further from the first conductive structure as compared to the second conductive structure.

Example 50 includes the apparatus of any of Examples 42 to 49, wherein the capacitively coupled device is in front-side layers of the IC die.

Example 51 includes the apparatus of any of Examples 42 to 49, wherein the capacitively coupled device is in back-side layers of the IC die.

Example 52 includes the apparatus of any of Examples 42 to 51, wherein the capacitively coupled device is part of a domino circuit.

Example 53 includes the apparatus of any of Examples 42 to 52, wherein the signal comprises a data path signal.

Example 54 includes the apparatus of any of Examples 42 to 52, wherein the signal comprises a processor data bus signal.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) die, comprising:
a first conductive structure for a terminal of a capacitively coupled device;
a second conductive structure aligned with the first conductive structure for a signal to be capacitively coupled to the terminal of the capacitively coupled device;
a first insulator material disposed between the first conductive structure and the second conductive structure, wherein the first insulator material comprises high gain insulator material; and
a cooling structure operable to remove heat from the capacitively coupled device to achieve an operating temperature at or below 0° C.

2. The IC die of claim 1, further comprising:
a first dielectric layer with the first conductive structure embedded therein; and
a second dielectric layer vertically adjacent to the first dielectric layer with the second conductive structure embedded therein, wherein the second conductive structure is vertically aligned with the first conductive structure.

3. The IC die of claim 1, wherein one or more of the first conductive structure and the second conductive structure comprises a metal material.

4. The IC die of claim 1, wherein the high gain insulator material comprises a high-k oxide material.

5. The IC die of claim 1, further comprising:
second insulator material in contact with the first conductive structure and the second conductive structure, wherein the second insulator material comprises lower gain insulator material as compared to the first insulator material.

6. The IC die of claim 5, further comprising:
a third conductive structure in contact with the second insulator material, wherein the third conductive structure is proximate to the first conductive structure and vertically spaced further from the first conductive structure as compared to the second conductive structure.

7. A system, comprising:
a substrate;
a power supply;
an integrated circuit (IC) die attached to the substrate and coupled to the power supply, the IC die comprising a first conductive structure for a terminal of a capacitively coupled device, a second conductive structure aligned with the first conductive structure for a signal to be capacitively coupled to the terminal of the capacitively coupled device, and a first insulator material disposed between the first conductive structure and the second conductive structure, wherein the first insulator material comprises high gain insulator material; and
a cooling structure operable to remove heat from the IC die to achieve an operating temperature at or below 0° C.

8. The system of claim 7 wherein the IC die further comprises:
a first dielectric layer with the first conductive structure embedded therein; and
a second dielectric layer vertically adjacent to the first dielectric layer with the second conductive structure embedded therein, wherein the second conductive structure is vertically aligned with the first conductive structure.

9. The system of claim 7, further comprising:
second insulator material in contact with the first conductive structure and the second conductive structure, wherein the second insulator material comprises lower gain insulator material as compared to the first insulator material.

10. The system of claim 9, further comprising:
a third conductive structure in contact with the second insulator material, wherein the third conductive structure is proximate to the first conductive structure and vertically spaced further from the first conductive structure as compared to the second conductive structure.

11. The system of claim 7, wherein the capacitively coupled device is in one of front-side and back-side layers of the IC die.

12. The system of claim 7, wherein the capacitively coupled device is part of a domino circuit.

13. The system of claim 7, wherein the signal comprises one of a data path signal and a processor data bus signal.

14. The system of claim 7, wherein the IC die comprises a plurality of metallization layers over a front side of the plurality of capacitively coupled devices, the metallization layers to provide signal routing for the plurality of capacitively coupled devices, and wherein the cooling structure is over the plurality of metallization layers.

15. The system of claim 14, wherein the cooling structure comprises a plurality of microchannels in the IC die and over the plurality of metallization layers, the microchannels to convey a heat transfer fluid therein.

16. The system of claim 15, wherein the cooling structure further comprises a chiller mounted to the IC die over the microchannels, the chiller comprising one of a solid body comprising second microchannels to convey a second heat transfer fluid therein or a heat sink for immersion in a low-boiling point liquid.

17. A method, comprising:
receiving a substrate;
forming a first conductive structure for a terminal of a capacitively coupled device;
forming a second conductive structure aligned with the first conductive structure for a signal to be capacitively coupled to the terminal of the capacitively coupled device;
forming a first insulator material between the first conductive structure and the second conductive structure, wherein the first insulator material comprises high gain insulator material; and
providing a cooling structure operable to remove heat from the capacitively coupled device to achieve an operating temperature at or below 0° C.

18. The method of claim 17, further comprising:
forming a first dielectric layer with the first conductive structure embedded therein; and
forming a second dielectric layer vertically adjacent to the first dielectric layer with the second conductive structure embedded therein, wherein the second conductive structure is vertically aligned with the first conductive structure.

19. The method of claim 17, further comprising:
forming a second insulator material in contact with the first conductive structure and the second conductive structure, wherein the second insulator material comprises lower gain insulator material as compared to the first insulator material.

20. The method of claim 19, further comprising:
forming a third conductive structure in contact with the second insulator material, wherein the third conductive structure is proximate to the first conductive structure and vertically spaced further from the first conductive structure as compared to the second conductive structure.
